(19) United States
(12) Patent Application Publication
(10) Pub. No.: US 2002/0119622 A1
(43) Pub. Date: Aug. 29, 2002

(54) Capacitor having a blended interface and a method of manufacture thereof

(76) Inventors: Michael L. Steigerwald, Martinsville, NJ (US); Yiu-Huen Wong, Summit, NJ (US); Susan M. Zahurak, Lebanon, PA (US)

Correspondence Address: Charles W. Gaines, Hitt Gaines & Boisbrun, P. C., P.O. Box 832570, Richardson, TX, 75083, US

(21) Appl. No.: 09/794,380

(22) Filed: Feb. 27, 2001

(51) Int. Cl. H01L 21/8242

(52) U.S. Cl. 438/244

(57) ABSTRACT

The present invention provides a method of manufacturing a capacitor on a semiconductor wafer. The method comprises placing a metal nitride film, such as a tantalum nitride film, on a substrate of a semiconductor wafer. A first electrode and a dielectric layer are created from the metal nitride film by subjecting the metal nitride film to a plasma oxidation process, which forms a blended interface between the first electrode and the dielectric layer. To complete the capacitor, a second electrode is formed over the dielectric. Interconnections with other semiconductor devices may also be formed on the wafer to create an operative integrated circuit.

### TECHNICAL FIELD OF THE INVENTION

The present invention is directed, in general, to the manufacture of semiconductor devices and, more specifically, to a a capacitor having a blended interface and a method of manufacture thereof.

### BACKGROUND OF THE INVENTION

As is well known, various semiconductor devices and structures are fabricated on semiconductor wafers in order to form operative integrated circuits (ICs). These various semiconductor devices and structures allow fast, reliable and inexpensive ICs to be manufactured for today's competitive computer and telecommunication markets. To keep such ICs inexpensive, the semiconductor manufacturing industry continually strives to economize each step of the IC fabrication process to the greatest extent, while maintaining the highest degree of quality and functionality as possible.

Among the processing steps sought to be made more efficient is the deposition or growth of the various layers of materials on the semiconductor wafer to form semiconductor devices. One specific example is the formation of metal-oxide-metal (MOM) and polysilicon-oxide-polysilicon (POP) capacitors, which have gained wide use in today's IC technology because of their ability to achieve a high capacitance value for a small area. In addition, such capacitors may be formed during the front-end of the manufacturing process (for instance, in dynamic random access memory (DRAM) applications) or at the back-end of manufacturing. In either case, such capacitors are commonly formed on a silicon substrate by depositing a bottom electrode, such as titanium (Ti) or tantalum (Ta) in the case of an MOM capacitor. Then a barrier layer, such as titanium nitride (TiN) or tantalum nitride (TaN) may be deposited over the bottom electrode. A dielectric material, such as silicon dioxide (SiO₂) or tantalum pentoxide (Ta₂O₅) is then deposited over the barrier layer, which serves as the dielectric. Following the deposition of the dielectric layer, an upper electrode is deposited over the dielectric layer, or optionally over another barrier layer deposited therebetween. Typically, physical vapor deposition (PVD) or chemical vapor deposition (CVD) is the technique used to deposit these various layers. The layers are then patterned and etched to form the desired capacitor structure.

As evidenced from the above, a disadvantage to using such capacitors is the number of processing steps involved in their formation. Since a deposition step is required for each layer of the capacitor, additional mask steps during the IC manufacturing process are also required. Those skilled in the art understand that numerous deposition and mask steps directly translate into increased device manufacturing costs, which in turn translate into an increase in the overall manufacturing cost and diminished chip yields of the entire IC. With the intense competition in today's IC manufacturing industry, such increases in cost in device layer fabrication are highly undesirable. Thus, among the areas where manufacturing costs may be curtailed is in the deposition or growth of device layers.

In addition, current methods used to form trench capacitors having high aspect ratios during front-end manufacturing often result in poor step coverage of the capacitor layers. Those skilled in the art understand that such poor step coverage may result in detrimental increases in resistance across the overall device, often caused by “bottle-necking” of device layers in the trench. Of course, this increase in device resistance is undesirable and potentially damaging to IC operation, especially in DRAM applications.

Accordingly, what is needed in the art is a method of forming semiconductor device layers, such as the layers of MOM capacitors, which continues to provide quality devices using the least number of processing steps possible. As a result, overall IC manufacturing costs are reduced, while chip yields are increased, without sacrificing device quality.

### SUMMARY OF THE INVENTION

To address the above-discussed deficiencies of the prior art, the present invention provides a method of manufacturing a capacitor on a semiconductor wafer. In an advantageous embodiment, the method comprises placing a metal nitride film, such as a tantalum nitride film, on a substrate of a semiconductor wafer. A first electrode and a dielectric are then created from the metal nitride film by subjecting the metal nitride film to a plasma oxidation process. In an advantageous embodiment, this process forms a dielectric that is highly amorphous and has nitrogen incorporated into the dielectric lattice. In addition, the unique use of the plasma oxidation process forms a capacitor device having a blended interface, which is a radical departure from the interfaces formed by differing crystalline structures, such as those found in the capacitors formed by the conventional techniques discussed above. To complete the capacitor, a second electrode is formed over the dielectric.

In addition, an integrated circuit may be manufactured, incorporating such capacitors, by forming transistors on a substrate and depositing an interlevel dielectric layer over the transistors. Capacitors formed according to the present invention are may be formed over this interlevel dielectric layer, or alternatively during front-end manufacturing of the IC (for example, for DRAM applications), using the method mentioned briefly above. Interconnects are then formed in the interlevel dielectric layers to interconnect the transistors and capacitors, as well as other devices or structures, to form an operative integrated circuit.

The foregoing has outlined, rather broadly, preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention in its broadest form.

### BRIEF DESCRIPTION OF THE DRAWINGS

For a more complete understanding of the present invention, reference is now made to the following descriptions taken in conjunction with the accompanying drawings, in which:

FIG. 1 illustrates a sectional view of an initial device from which a capacitor as provided by the present invention may be formed;

FIG. 2 illustrates a sectional view of the device of FIG. 1 being subjected to plasma oxidation;

FIG. 3 illustrates a close-up sectional view of the device of FIG. 2 after undergoing plasma oxidation;

FIG. 4 illustrates a sectional view of the metal nitride film following the plasma oxidation and the deposition of a second electrode over the dielectric; and

FIG. 5 illustrates a sectional view of a conventional integrated circuit incorporating the completed capacitor illustrated in FIG. 4, as well as one embodiment of a trench capacitor manufactured according to the present invention.

### DETAILED DESCRIPTION

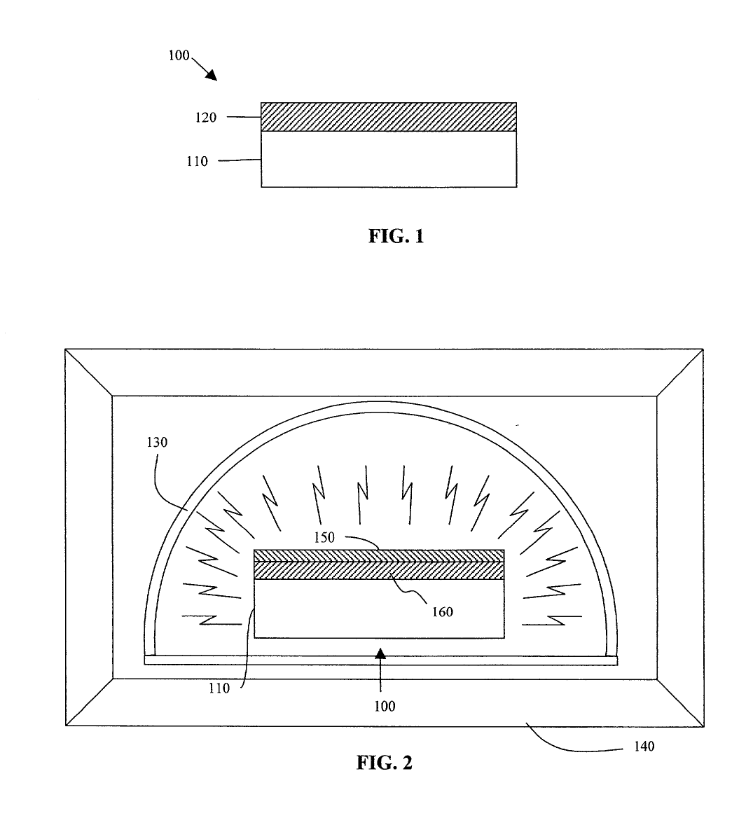

Referring initially to FIG. 1, there is illustrated an initial device 100 from which a capacitor as provided by the present invention may be formed. As illustrated, the device 100 is formed on a substrate 110 of a semiconductor wafer, which may be an interlevel dielectric during back-end manufacturing of an IC or during front-end manufacturing. However, it should be noted that any other substrate found within the semiconductor wafer itself, or the layers formed thereon may also serve as an appropriate substrate.

An advantageous embodiment of the present invention includes a method of forming a metal nitride film 120 on the substrate 110. The metal nitride film 120 may be selected from a number of metal nitrides that are often used in the manufacture of semiconductor devices. For example, the metal nitride film 120 may be tantalum nitride or titanium nitride. Other exemplary materials may include tungsten nitride (WN), molybdenum nitride (MbN), zirconium nitride (ZrN) and hafnium nitride (HfN), however the present invention is not limited to a particular material. The metal nitride film 120 may be conventionally formed on the substrate 110. Of course, the present invention is broad enough to encompass other deposition or growth processes of forming the metal nitride 120 on the substrate 110. For example, in an advantageous embodiment, the metal nitride film 120 may be sputter-deposited onto the substrate 110. However, in alternative embodiments, chemical vapor deposition (CVD), physical vapor deposition (PVD), or other appropriate techniques, can be used to deposit or grow the metal nitride film 120 on the substrate 110. Those skilled in the art understand the CVD and PVD processes, as well as other similar techniques, and the advantages and disadvantages associated with those techniques.

In an exemplary embodiment, the metal nitride film 120 is tantalum nitride and is placed on the substrate 110 to a thickness ranging from about 50 nm to about 100 nm. In a more specific embodiment, the thickness of the metal nitride film 120 is about 75 nm. Although the present invention is described in terms of specific ranges, these thicknesses are for illustrative purposes only and are not intended to limit the present invention to any particular thickness of the metal nitride film 120.

Turning now to FIG. 2, illustrated is a sectional view of the device 100 of FIG. 1 being subjected to plasma oxidation. In an advantageous embodiment, the plasma oxidation is a microwave plasma oxidation process. In an exemplary embodiment, plasma oxidation of the metal nitride film 120 is conducted by placing the entire substrate 110 within a vacuum chamber 130 so that the ambient gases may be evacuated from the vacuum chamber 130. In this particular embodiment, the vacuum chamber 130 is evacuated to a pressure of 3 millitorr, however the present invention is not so limited. Then, oxygen is introduced into the vacuum chamber 130 at a relatively low flow rate, for example, 5 sccm. In an advantageous embodiment, the evacuation of the vacuum chamber 130 to 3 millitorr, combined with the introduction of oxygen at 5 sccm, results in a final chamber pressure ranging from about 0.5 to about 1.0 torr. The vacuum chamber 130 is then placed in a microwave reactor 140.

When a microwave is used to conduct the plasma oxidation, the microwave reactor 140 applies microwaves to the vacuum chamber 130 having a microwave power ranging from about 300 W to about 600 W for a predetermined duration, which depends on design parameters. In a more specific embodiment, the microwave reactor 140 applies microwaves to the vacuum chamber 130 having a microwave power of about 480 W for about 10 minutes at a frequency of about 2.46 GHz. After the time has expired, the device 100 is allowed to cool, and the vacuum chamber 130 may be vented with nitrogen (N₂). Once the plasma oxidation process is completed, the device 100 is removed from the microwave reactor 140. If desired, the device 100 may then be annealed using conventional techniques, however experiments using the method of the present invention have produced dielectric layers that are quite insulating (e.g., less electrical leakage) even without the post-annealing process typically required with deposition techniques found in the prior art. As a result, post-deposition annealing may not be necessary with the present invention.

As a result of the plasma oxidation process, an upper portion of the metal nitride film 120 is oxidized and transformed into a dielectric 150. Consequently, the remaining portion of the metal nitride film 120 forms a first electrode 160. In one embodiment, the dielectric 150 is created having a thickness ranging from about 12 nm to about 15 nm. Additionally, in such an embodiment, the first electrode 160 has a thickness ranging from about 38 nm to about 85 nm. In a more specific embodiment, the portion of the metal nitride film 120 transformed into the dielectric 150 is about 13 nm when the original thickness of the metal nitride film 120 is about 75 nm.

When tantalum nitride is the metal nitride film 120, the plasma oxidation process forms a tantalum oxide layer for the dielectric layer 150. Thus, the material constituting the first electrode 160 of the capacitor and the dielectric layer 150 depends on the metal nitride used. Since, the plasma oxidation process transforms a portion of the metal nitride film 120 into a dielectric 150 it is possible that the dielectric 150 will contain a nitrided oxide. In such instances, the nitrogen may either be chemically bonded with the dielectric material, or it may simply be present within the lattice. Whether nitrided or not, the dielectric 150, when formed from the metal nitride film 120 through a plasma oxidation process, is highly amorphous in composition even when formed at relatively low temperatures.

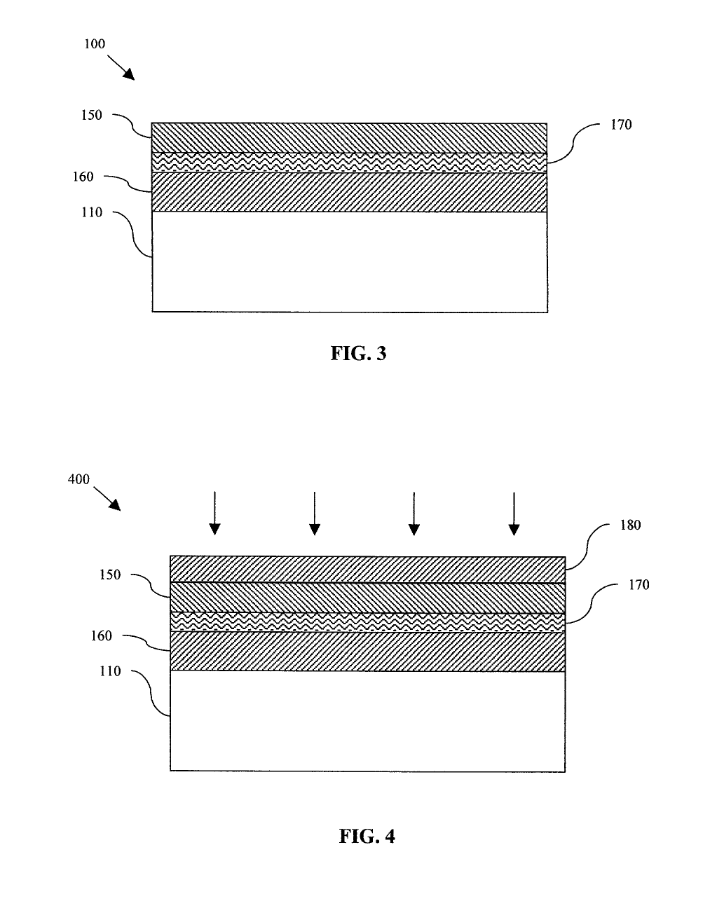

Turning now to FIG. 3, illustrated is a close-up sectional view of the device 100 of FIG. 2, after undergoing plasma oxidation. As the plasma oxidation of the metal nitride film 120 is conducted to form the first electrode 160 and the dielectric 150, a blended interface 170 is formed between the first electrode 160 and the dielectric 150. As used with regard to the present invention, the term “blended interface” means a region between the first electrode 160 and the dielectric 150 in which the elemental composition transforms from predominately metal nitride to predominately metal oxide, when moving from the first electrode 160 to the dielectric 150.

This blended interface 170, illustrated in FIG. 3, offers distinct advantages over the interfaces formed by conventional techniques. For example, in conventional processes, the abrupt interface between the first electrode and the dielectric (or diffusion barrier) is often formed by differences in grain crystalline structures of the different deposited materials. This “sharp” interface is often problematic in the device's operation due primarily to the bonding discontinuities likely caused by unpassivated defects at the interface of the two distinct materials. Those skilled in the art understand the general rule that the larger the number of defects in a device layer, the greater the leakage current experienced through that layer. With the blended interface provided by the present invention, the gradual transformation from one material to another, rather than the abrupt transformation found in the prior art, allows for a slow enough change in local structure that such bonding discontinuities are suppressed. As a result, leakage current through the device layers forming the blended interface are also reduced.

Referring now to FIG. 4, illustrated is a sectional view of the metal nitride film 120 following the plasma oxidation and the deposition of a second electrode 180 over the dielectric 150. Following the formation of the first electrode 160 and the dielectric 150, the device 100 of FIG. 3 is removed from the vacuum chamber 130. The second electrode 180 is then conventionally deposited on the dielectric 150. In an advantageous embodiment, the second electrode 180 is formed from platinum, tantalum, tantalum nitride, titanium nitride, or aluminum. Of course, any metal suitable for use as a second electrode of a capacitor may also be placed atop the dielectric 150.

As with the first electrode 160, in an exemplary embodiment the second electrode 180 may be deposited using conventional, low temperature techniques. For example, in a preferred embodiment, the second electrode 180 is deposited using PVD. The relatively low ambient temperature required with PVD allows the second electrode 180 to be deposited during back-end manufacturing with little or no risk of damage to the front-end components of the semiconductor wafer.

By using the plasma oxidation process to transform a portion of the metal nitride film 120 into a dielectric 150 rather than depositing the dielectric 150 over the first electrode 160 as is known in the prior art, the present invention gains significant advantages over the techniques found in the prior art. Specifically, by eliminating the oxide deposition step the method of the present invention reduces the number of steps required to manufacture the capacitor 400. In addition, by reducing the steps required the time of manufacturing is also reduced, resulting in significant cost savings to semiconductor manufacturers. The plasma oxidation process further results in the dielectric 150 having an extremely amorphous molecular structure. Those skilled in the art understand that semiconductor devices having highly amorphous dielectric layers are highly desirable in the semiconductor manufacturing industry since amorphous structures are typically less susceptible to leakage currents.

Yet another advantage of the present invention is the relatively low thermal budget maintainable with the plasma oxidation process. During the manufacture of an operative integrated circuit on a wafer, certain semiconductor devices, such as metal-oxide-metal (MOM) and polysilicon-oxide-polysilicon (POP) capacitors, may not be manufactured until near the end of the manufacturing process, the so-called back-end of the process. Many conventional techniques are not suited for back-end manufacturing because of the extreme temperatures required. Those skilled in the art understand the significant damage that may be inflicted on the front-end devices of a semiconductor wafer by such high-temperature techniques. Since the plasma oxidation process typically occurs with an ambient temperature of about 250° C., the method of the present invention is better suited for back-end manufacturing than many of the techniques found in the prior art.

Still a further advantage of the method of the present invention is the exceptional step coverage obtainable. Specifically in the formation of trench capacitors, perhaps during front-end manufacturing, techniques found in the prior art which deposit layer atop of layer often do so with poor step coverage. This poor step coverage often causes layers of the capacitor to bottle-neck in the trench, resulting in increased resistance across the entire trench capacitor. Such harmful parasitic resistance is typically detrimental to device operation, however is especially undesirable in DRAM applications. By using techniques found in the prior art, any imprecision in step coverage from depositing the dielectric layer is accumulated onto the imprecise step coverage already present from the earlier deposition of the metal nitride film. However, by using the plasma oxidation process of the present invention to transform a portion of a metal nitride film into a dielectric layer, imprecisions in step coverage from the dielectric layer are not accumulated onto imprecisions in step coverage of the metal nitride film. Instead, because the dielectric is formed from an outer portion of the metal nitride film, only the imprecisions in step coverage from the original deposition of the metal nitride film remain. Thus, although further imprecisions in step coverage may result from deposition of the upper electrode, the overall step coverage of a trench capacitor manufactured according to the principles of the present invention is improved over the prior art.

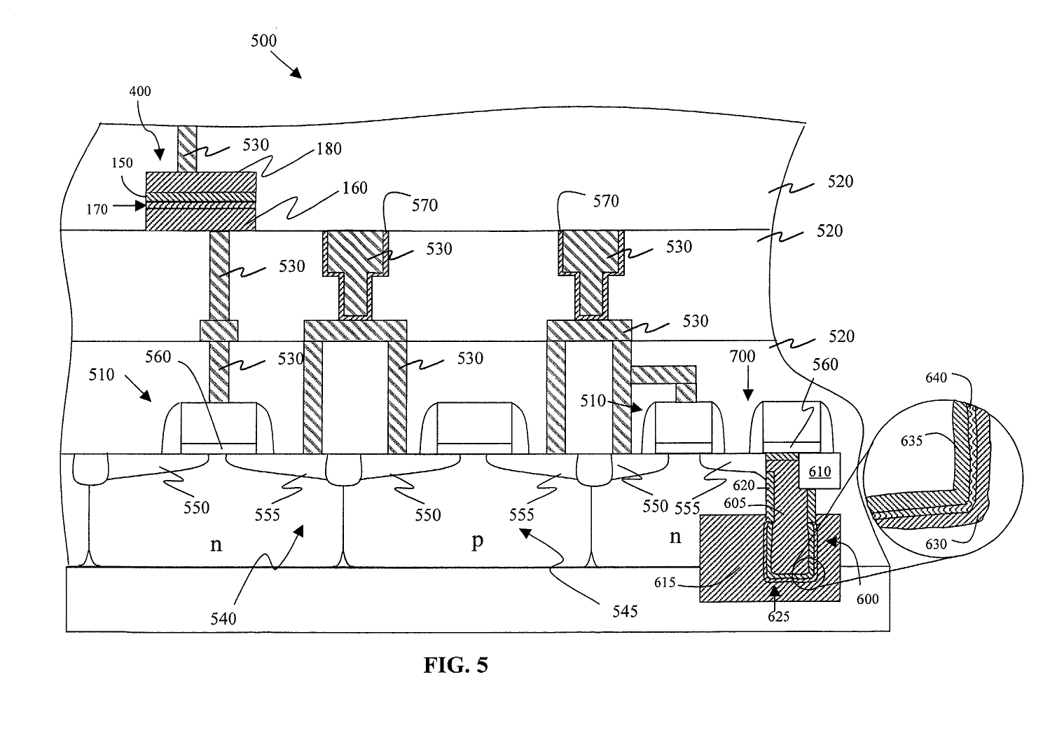

Turning finally to FIG. 5, illustrated is a sectional view of a conventional integrated circuit (IC) 500 incorporating the completed capacitor 400 illustrated in FIG. 4, as well as one embodiment of a trench capacitor 600 manufactured according to the present invention. The trench capacitor 600 is part of a trench DRAM 700, however other embodiments of the trench capacitor 600 are still within the scope of the present invention. The IC 500 may also include active devices, such as transistors, used to form CMOS devices, BiCMOS devices, Bipolar devices, or other types of active devices. The IC 500 may further include passive devices such as inductors, resistors, or the IC 500 may also include optical and optoelectronic devices, and the like. Those skilled in the art are familiar with the various types and manufacture of devices which may be located in the IC 500.

In the embodiment illustrated in FIG. 5, the active devices are shown as transistors 510. As illustrated, the transistors 510 have gate oxide layers 560 formed on a semiconductor wafer. The transistors 510 may be metal-oxide semiconductor field effect transistors 510 (MOSFETS), however other types of transistors are within the scope of the present invention. Interlevel dielectric layers 520 are then shown deposited over the transistors 510.

The capacitor 400 is formed over the interlevel dielectric layers 520, in accordance with the principles of the plasma oxidation of a metal nitride film described above. In addition, FIG. 5 illustrates the blended interface 170 between the dielectric 150 and the first electrode 160 mentioned above. Interconnect structures 530 are formed in the interlevel dielectric layers 520 to form interconnections between the transistors 510 and the capacitor 400 to form an operative integrated circuit. Also illustrated are conventionally formed tubs 540, 545, source regions 550, and drain regions 555.

The trench capacitor 600 includes a trench 605, an isolation structure 610, and extends into a buried n-plate 615. A dielectric strap 620 insulates the trench 605 from other parts of the IC 500. The trench capacitor 600 further includes a node dielectric 625 formed in the n-plate 625. A close-up view of the node dielectric 625 illustrates an electrode 630, which originated as portion of a metal nitride film. Following the method of the present invention, the metal nitride film was subjected to a plasma oxidation process resulting in the film becoming the electrode 630 and a dielectric 635. In addition, in the illustrated embodiment, plasma oxidation according to the principles of the present invention also creates a blended interface 640 between the first electrode 630 and the dielectric 635.

In the illustrated embodiment of the capacitor 400, the metal nitride film 120, from which the dielectric 150 and first electrode 160 are created, also forms a barrier layer 570. More specifically, when the upper interconnections are formed in the interlevel dielectric layers 520, the metal nitride film 120 is incorporated into the interconnect structures 530 to reduce the number of processing steps required to form those interconnect structures 530. Those skilled in the art understand the benefits of forming barrier layers 570 between semiconductor devices in an integrated circuit, as well as reducing processing steps.

Also in the illustrated embodiment, one of the interconnect structures 530 is shown connecting one of the transistors 510 to the capacitor 400. In addition, the interconnect structures 530 also connect the transistors 510 to other areas or components of the IC 500, including the trench DRAM 700. Although only shown interconnected with a single transistor 510, the capacitor 400 and the trench DRAM 700 may also be connected to other semiconductor devices formed on the IC 500.

Of course, use of the method of manufacturing semiconductor devices of the present invention is not limited to the manufacture of the particular IC 500 illustrated in FIG. 5. In fact, the present invention is broad enough to encompass the manufacture of any type of integrated circuit formed on a semiconductor wafer, which would benefit from the reduced processing steps, improved step coverage and low thermal budget provided by plasma oxidation of a metal nitride film. In addition, the present invention is broad enough to encompass integrated circuits having greater or fewer components, than illustrated in the IC 500 of FIG. 5. Moreover, the principles of the present invention may also be employed to form portions of some or all of these other devices, including but not limited to the gate oxide layers 560 of one or more of the transistors 510 illustrated in FIG. 5. Beneficially, each time the method of the present invention is employed to form part or all of a semiconductor device, costly manufacturing steps may be eliminated from the entire manufacturing process.

Although the present invention has been described in detail, those skilled in the art should understand that they can make various changes, substitutions and alterations herein without departing from the spirit and scope of the invention in its broadest form.

What is claimed is:

1. A method of manufacturing a capacitor, comprising:
placing a metal nitride film on a substrate;
creating a first electrode and a dielectric from the metal nitride film by subjecting the metal nitride film to a plasma oxidation process; and
forming a second electrode over the dielectric.

2. The method as recited in claim 1 wherein placing includes placing a tantalum nitride or titanium nitride film on the substrate.

3. The method as recited in claim 1 wherein placing includes placing a tantalum nitride film on the substrate and creating includes forming a first electrode comprising tantalum nitride and forming a dielectric includes forming tantalum oxide or tantalum pentoxide from the tantalum nitride film.

4. The method as recited in claim 1 wherein creating includes oxidizing a portion of a thickness of the metal nitride film wherein the portion ranges from about 12 nm to about 15 nm.

5. The method as recited in claim 1 wherein placing includes placing a metal nitride film on the substrate having a thickness ranging from about 50 nm to about 100 nm.

6. The method as recited in claim 1 wherein subjecting includes subjecting the metal nitride film to a microwave plasma oxidation process wherein a microwave power ranges from about 300 watts to about 600 watts.

7. The method as recited in claim 1 wherein creating a dielectric includes creating a dielectric comprising a nitrided oxide.

8. The method as recited in claim 1 wherein creating includes creating in a pressure ranging from about 0.5 torr to about 1.0 torr.

9. The method as recited in claim 1 wherein placing a metal nitride film on the substrate includes placing the metal nitride film within a trench formed in the substrate and the method further includes forming a trench capacitor within the trench.

10. A method of fabricating an integrated circuit, comprising:
forming active devices over a semiconductor wafer;
forming capacitors over a substrate of semiconductor wafer, including:
placing a metal nitride film on a substrate;
creating first electrodes and dielectrics from the metal nitride film by subjecting the metal nitride film to a plasma oxidation process; and
forming second electrodes over the dielectrics; and
interconnecting the active devices and capacitors to form an operative integrated circuit.

11. The method as recited in claim 10 wherein creating dielectrics includes oxidizing a portion of the metal nitride film to form a nitrided oxide over the metal nitride film.

12. The method as recited in claim 10 wherein oxidizing includes oxidizing a portion of a thickness of the metal nitride film wherein the portion ranges from about 12 nm to about 15 nm.

13. The method as recited in claim 10 wherein the metal nitride film is tantalum nitride or titanium nitride.

14. The method as recited in claim 10, wherein placing includes placing a tantalum nitride film on the substrate and creating includes forming first electrodes comprising tantalum nitride and forming dielectrics includes forming tantalum oxide or tantalum pentoxide from the tantalum nitride film.

15. The method as recited in claim 10 wherein subjecting includes subjecting the metal nitride film to a microwave plasma oxidation process wherein a microwave power ranges from about 300 watts to about 600 watts.

16. The method as recited in claim 10 wherein forming interconnects includes incorporating the metal nitride film into the interconnects as a barrier layer.

17. The method as recited in claim 10 wherein placing a metal nitride film on the substrate includes placing the metal nitride film within a trench formed in the substrate and the method futher includes forming a trench capacitor within the trench.

18. A capacitor comprising:
a first nitride metal electrode;
a dielectric located over the first nitride metal electrode, the dielectric including an oxide of the nitride metal electrode;
a blended interface interposed between the first nitride metal electrode and the dielectric; and
a second electrode located over the dielectric.

19. The capacitor as recited in claim 18 wherein the first nitride metal electrode comprises tantalum nitride and the dielectric comprises a tantalum oxide containing nitrogen.

20. The capacitor as recited in claim 18 wherein a thickness of the first nitride metal electrode ranges from about 38 nm to about 85 nm and a thickness of the dielectric ranges from about 12 nm to about 15 nm.

21. The capacitor as recited in claim 18 wherein the dielectric is amorphous.

22. The capacitor as recited in claim 18 wherein the first nitride metal electrode is tantalum nitride, titanium nitride, tungsten nitride, molybdenum nitride, zirconium nitride, or hafnium nitride, and the second electrode is platinum, tantalum, tantalum nitride, titanium nitride, or aluminum.

23. The capacitor as recited in claim 18 wherein the capacitor is a trench capacitor located within an active device region of an integrated circuit.
